(19) United States
(12) Patent Application Publication
(10) Pub. No.: US 2016/0035647 A1
(43) Pub. Date: Feb. 4, 2016

(54) SEMICONDUCTOR DEVICE HAVING HEAT DISSIPATION STRUCTURE AND LAMINATE OF SEMICONDUCTOR DEVICES

(71) Applicant: Panasonic Corporation, Osaka (JP)

(72) Inventor: TAKAO OCHI, Niigata (JP)

(21) Appl. No.: 14/885,222

(22) Filed: Oct. 16, 2015

Related U.S. Application Data
(63) Continuation of application No. PCT/JP2014/000546, filed on Feb. 3, 2014.

(30) Foreign Application Priority Data
May 23, 2013 (JP) 2013-108759

(51) Int. Cl. H01L 23/367; H01L 23/31

(52) U.S. Cl. CPC H01L 23/3677; H01L 23/3107

(57) ABSTRACT

A semiconductor device includes a semiconductor substrate, an electrode arranged on a first surface of the semiconductor substrate, a circuit formed on a second surface, of the semiconductor substrate, on an opposite side from the first surface, a conductor connecting the circuit and the electrode, a first lead arranged on an outer periphery of the semiconductor substrate, a connection member connecting the electrode and the first lead, and a sealing material sealing the semiconductor substrate, the first lead, and the connection member, where the second surface of the semiconductor substrate is exposed from the sealing material.

### BACKGROUND OF THE INVENTION

1. Field of the Invention

The present disclosure relates to a semiconductor device having a heat dissipation structure and a manufacturing method thereof.

2. Description of the Related Art

In the following, a structure of a semiconductor device according to PTL 1 will be described with reference to FIG. 13. FIG. 13 is a cross-sectional diagram of the semiconductor device according to PTL 1.

As shown in FIG. 13, the semiconductor device is formed from semiconductor substrate 101, wires 102, sealing resin 103, and leads 104, and leads 104 are disposed at an outer periphery of semiconductor substrate 101.

A circuit including electrodes 108 is formed on the upper surface side of semiconductor substrate 101, and electrodes 108 of semiconductor substrate 101 and internal terminals 127 of leads 104 are connected by wires 102.

Semiconductor substrate 101, leads 104, and wires 102 are seal-molded with sealing resin 103, and lower surface 106 of semiconductor substrate 101 and lower surfaces 126 of leads 104 are exposed from sealing resin 103 at the lower surface of the semiconductor device.

A structure of a semiconductor device according to PTL 2 will be described with reference to FIG. 14. FIG. 14 is a cross-sectional diagram of the semiconductor device according to PTL 2.

As shown in FIG. 14, the semiconductor device is formed from semiconductor substrate 101, wires 102, sealing resin 103, and leads 104, and leads 104 are disposed at an outer periphery of semiconductor substrate 101.

A circuit including electrodes 108 is formed on the upper surface side of semiconductor substrate 101, electrodes 108 of semiconductor substrate 101 and internal terminals 127 of leads 104 are connected by wires 102, and semiconductor substrate 101, leads 104, and wires 102 are sealed with sealing resin 103.

The thickness of semiconductor substrate 101 is thinner than that of leads 104, leads 104 each include a step, and internal terminals 127 are formed one step lower than top surfaces 125 of leads 104.

Lower surfaces 126 of leads 104 and lower surface 106 of semiconductor substrate 101 are exposed, at the lower surface of the semiconductor device, outside sealing resin 103 on the same plane, and upper surfaces 125 of leads 104 are exposed outside at the upper surface of the semiconductor device.

### CITATION LIST

### Patent Literatures

PTL 1: Unexamined Japanese Patent Publication No. 2006-196556
PTL 2: Unexamined Japanese Patent Publication No. 2001-177005

The conventional technologies described above have the following problems in terms of heat dissipation.

(Problem 1) The circuit of the semiconductor substrate is formed on the upper surface of the semiconductor substrate and is covered with the sealing resin, and thus heat dissipation from the circuit is poor.

(Problem 2) To cope with the problem of heat dissipation described above, there is a method for externally attaching a heat sink, but in this case, the thickness of the package is increased, and reduction in the thickness becomes difficult. Also, the number of steps is increased, and as a result, the production efficiency is reduced and the manufacturing cost is increased.

(Problem 3) In the case where a plurality of semiconductor devices are laminated, the semiconductor substrate at each layer is sandwiched by lower and upper semiconductor devices, and heat dissipation is further reduced.

### SUMMARY OF THE INVENTION

In view of the above problems, an object of the present disclosure is to provide a semiconductor device which has high heat dissipation and whose thickness may be reduced, and a laminate of such semiconductor devices.

A semiconductor device according to the present disclosure includes a semiconductor substrate, an electrode disposed on a first surface of the semiconductor substrate, a circuit formed on a second surface, of the semiconductor substrate, on an opposite side from the first surface, and a conductor connecting the circuit and the electrode. The semiconductor device further includes a first lead disposed on an outer periphery of the semiconductor substrate, a connection member connecting the electrode and the first lead, and a sealing material sealing the semiconductor substrate, the first lead, and the connection member, where the second surface of the semiconductor substrate is exposed from the sealing material.

Further, in the semiconductor device, an insulating film arranged to cover the circuit, and a metal film disposed to cover the insulating film may be provided on the second surface of the semiconductor substrate.

In the semiconductor device according to the present disclosure, a surface of the semiconductor substrate on which the circuit is disposed and a surface of the semiconductor substrate on which the electrode is disposed may be separated by the conductor. Accordingly, by forming the circuit on the second surface of the semiconductor substrate and exposing the circuit from the sealing material, a semiconductor device with high heat dissipation may be realized while keeping the semiconductor device thin by not externally attaching an additional member for heat dissipation.

Furthermore, in another semiconductor device according to the present disclosure, the second surface of the semiconductor substrate may be covered by a metal film and exposed from the sealing material, and thus further enhanced heat dissipation may be realized.

### BRIEF DESCRIPTION OF DRAWINGS

FIG. 1A is a cross-sectional diagram of a semiconductor device according to a first exemplary embodiment;

FIG. 1B is an enlarged cross-sectional diagram of a semiconductor substrate used for the semiconductor device according to the first exemplary embodiment;

FIG. 2 is a cross-sectional diagram of a semiconductor device according to a second exemplary embodiment;

FIG. 3A is a cross-sectional diagram of a laminate of semiconductor devices according to a modification of the second exemplary embodiment;

FIG. 3B is a cross-sectional diagram of the laminate of semiconductor devices according to the modification of the second exemplary embodiment;

FIG. 4A is a diagram showing a structure of a semiconductor device according to a third exemplary embodiment, and is a top view showing sealing material 3 in a see-through manner;

FIG. 4B is a diagram showing the structure of the semiconductor device according to the third exemplary embodiment, and is a cross-sectional diagram along the line IVb-IVb in FIG. 4A;

FIG. 4C is a diagram showing the structure of the semiconductor device according to the third exemplary embodiment, and is a cross-sectional diagram along the line IVc-IVc in FIG. 4A;

FIG. 4D is a top view showing the structure of the semiconductor device according to the third exemplary embodiment;

FIG. 4E is a bottom view showing the structure of the semiconductor device according to the third exemplary embodiment;

FIG. 5 is a diagram for illustrating a first example of a manufacturing process for the semiconductor device according to the third exemplary embodiment;

FIG. 6 is a diagram for illustrating a second example of the manufacturing process for the semiconductor device according to the third exemplary embodiment;

FIG. 7 is a diagram for illustrating a third example of the manufacturing process for the semiconductor device according to the third exemplary embodiment;

FIG. 8A is a cross-sectional diagram of a laminate of semiconductor devices according to a first modification of the third exemplary embodiment;

FIG. 8B is a cross-sectional diagram of the laminate of semiconductor devices according to the first modification of the third exemplary embodiment;

FIG. 9 is a top view of a connected body of semiconductor devices according to a second modification of the third exemplary embodiment;

FIG. 10A is a diagram showing a structure of a semiconductor device according to a fourth exemplary embodiment, and is a top view showing sealing material 3 in a see-through manner;

FIG. 10B is a diagram showing the structure of the semiconductor device according to the fourth exemplary embodiment, and is a cross-sectional diagram along the line Xb-Xb in FIG. 10A;

FIG. 10C is a diagram showing the structure of the semiconductor device according to the fourth exemplary embodiment, and is a cross-sectional diagram along the line Xc-Xc in FIG. 10A;

FIG. 10D is a top view showing the structure of the semiconductor device according to the fourth exemplary embodiment;

FIG. 10E is a bottom view showing the structure of the semiconductor device according to the fourth exemplary embodiment;

FIG. 11A is another example of the bottom view of the semiconductor device according to the fourth exemplary embodiment;

FIG. 11B is another example of the bottom view of the semiconductor device according to the fourth exemplary embodiment;

FIG. 12 is a top view of a connected body of semiconductor devices according to a modification of the fourth exemplary embodiment;

FIG. 13 is a configuration diagram of a conventional semiconductor device; and

FIG. 14 is another configuration diagram of a conventional semiconductor device.

### DETAILED DESCRIPTION OF THE PREFERRED EMBODIMENTS

Hereinafter, exemplary embodiments will be described in detail with reference to the drawings as appropriate. However, unnecessarily detailed description may be omitted. For example, detailed description of already well-known matters and repeated description of substantially the same structure may be omitted. All of such omissions are intended to facilitate understanding by those skilled in the art by preventing the following description from becoming unnecessarily redundant.

Moreover, the inventor provides the appended drawings and the following description for those skilled in the art to fully understand the present disclosure, and does not intend to limit the subject described in the claims by the appended drawings and the following description.

### First Exemplary Embodiment

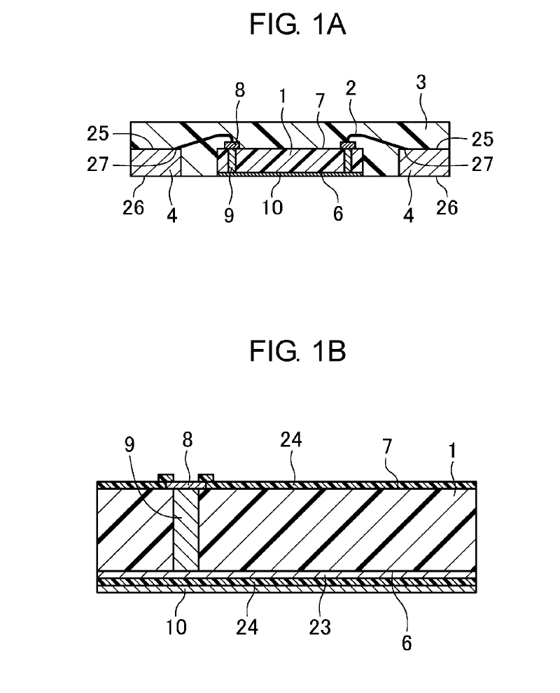

In the following, a structure of a semiconductor device according to a first exemplary embodiment will be described with reference to FIGS. 1A and 1B.

As shown in FIG. 1A, the semiconductor device according to the first exemplary embodiment includes semiconductor substrate 1, connection members 2, sealing material 3, and leads 4, which are first leads.

As shown in FIG. 1B, semiconductor substrate 1 includes electrodes 8 on first surface 7, and circuit 23 on second surface 6, and includes conductors 9 electrically connecting electrodes 8 and circuit 23.

Furthermore, insulating film 24 is desirably arranged, on circuit 23, on second surface 6 of semiconductor substrate 1, and metal film 10 is desirably provided so as to cover insulating film 24.

Connection member 2 is a thin metal line such as a wire, and an Au wire, a Cu wire, an Al wire or the like may be used therefor.

Sealing material 3 is for sealing semiconductor substrate 1, connection members 2, and leads 4, and is generally resin. For example, a thermosetting resin obtained by adding an Si filler to an epoxy resin is used.

Leads 4 are disposed at an outer periphery of semiconductor substrate 1. Also, semiconductor substrate 1 and leads 4 are disposed at a lowermost layer of the semiconductor device, and second surfaces are exposed from sealing material 3. Electrodes 8 disposed on first surface 7 of semiconductor substrate 1 and internal terminals 27 of leads 4 are connected by connection members 2.

Additionally, second surfaces 26 of leads 4 and second surface 6 of semiconductor substrate 1 may be exposed to outside on the same plane.

The base material of leads 4 is Cu or Fe, and Cu on which Ni, Pd and Au coatings are laminated, or Cu on which Ni, Pd and Ag coatings are laminated, or a Fe—Ni alloy coated with Ag may be used, for example.

First surfaces 25 of leads 4 may be at the same height as first surface 7 of semiconductor substrate 1.

Electrodes 8 formed on first surface 7 of semiconductor substrate 1 are of Al, for example, or they may be formed by laminating Cu, Ni and Au.

Electrodes 8 and circuit 23 are connected by conductors 9 that electrically connect first surface 7 and second surface 6 of semiconductor substrate 1. For example, conductors 9 are through electrodes penetrating from first surface 7 to second surface 6, and may be formed by a method for forming an insulating layer of SiO₂ or the like on a through hole formed in silicon, and then performing vapor deposition of Ti and Cu and coating with Cu. Note that, the shape of conductors 9 is arbitrary.

By using conductors 9, circuit 23 and electrodes 8 of semiconductor substrate 1 may be separated and arranged on first surface 6 and second surface 7, respectively. First surface 6 that generates a large amount of heat may thereby be exposed from sealing material 3, and a semiconductor device with enhanced heat dissipation may be obtained. Also, since there is no need to externally attach a heat sink or the like to enhance heat dissipation, the thickness of the semiconductor device may be kept thin.

Insulating film 24 for covering circuit 23 is arranged on second surface 6 of semiconductor substrate 1. Insulating film 24 is a film of SiO₂, SiN, or polyimide, for example. Insulating film 24 may cover the entire surface of second surface 6 where circuit 23 is formed, or may cover only the region where circuit 23 is exposed. The material and thickness of insulating film 24 may be any material and thickness as long as circuit 23 is insulated from outside semiconductor substrate 1. Moreover, from the standpoint of reducing the thickness of the semiconductor device, thinner insulating film 24 is more desirable.

Furthermore, a surface of insulating film 24 opposite a surface facing circuit 23 is covered by metal film 10. For example, metal film 10 is a Cu or Al film, and if further surface protection or connection is necessary, the surface may be covered by a laminate of Cu, Ni and Au coatings, a laminate of Cu, Ni and Pd coatings, solder or the like. Metal film 10 is exposed from sealing material 3, and is exposed to outside the semiconductor device. From the standpoint of heat dissipation, metal film 10 desirably covers the entire surface of insulating film 24.

Additionally, the exposed surface of metal film 10 and second surfaces 26 of leads 4 may be on the same plane.

As described above, semiconductor substrate 1 is arranged with a side of second surface 6 at the lowermost layer of the semiconductor device, and has a die pad-less structure.

As described above, according to the semiconductor device of the present exemplary embodiment, by using conductors 9, circuit 23 and electrodes 8 of semiconductor substrate 1 may be separated and arranged on first surface 7 and second surface 6, respectively. Furthermore, covering by high thermal conductive insulating film 24 and metal film 10 allows the outermost surface of high thermal conductive insulating film 24 to be exposed from the semiconductor device without being covered by low thermal conductive sealing material 3, and high heat dissipation may be achieved. Also, since there is no need to externally attach a heat sink or the like to enhance heat dissipation, the thickness of the semiconductor device may be reduced as much as possible. Furthermore, a step necessary for attaching the heat sink does not have to be added, and thus it is possible to perform manufacturing without the productivity being reduced. Moreover, the outer shape of the semiconductor device may be made the same as the outer shape of the semiconductor device in which a heat sink is not provided, and handling is easy compared to a case where the heat sink is externally attached.

### Second Exemplary Embodiment

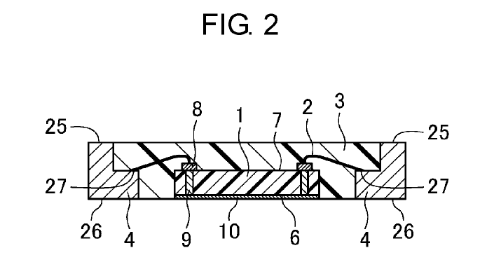

In the following, a structure of a semiconductor device according to a second exemplary embodiment will be described with reference to FIG. 2. Description will be given mainly on differences from the first exemplary embodiment.

In the present exemplary embodiment, leads 4 each include a step on the side facing semiconductor substrate 1. Specifically, internal terminals 27 of leads 4 are formed to be lower than first surfaces 25 of leads 4. The number of steps between internal terminals 27 and first surfaces 25 of leads 4 is arbitrary.

As shown in FIG. 2, electrodes 8 on first surface 7 of semiconductor substrate 1 and internal terminals 27 of leads 4 are connected by connection members 2, but due to the steps described above, the height of the crests of connection members 2 is lower than the height of first surfaces 25 of leads 4.

As described above, in the semiconductor device according to the present exemplary embodiment, second surfaces 26 of leads 4 and second surface 6 of semiconductor substrate 1 are exposed from sealing material 3, and first surfaces 25 of leads 4 are also exposed from sealing material 3. That is, leads 4 may be exposed at the upper and lower surfaces of the semiconductor device, and thus a thin semiconductor device having high heat dissipation may be easily manufactured.

Additionally, metal film 10 covering second surface 6 of semiconductor substrate 1 and second surfaces 26 of leads 4 may be exposed from sealing material 3 on the same plane.

### Modification of Second Exemplary Embodiment

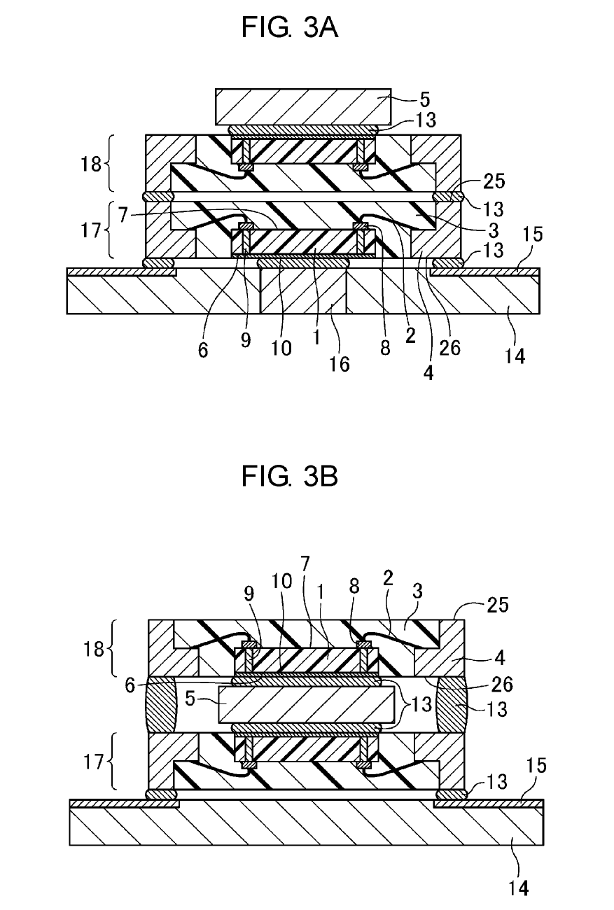

Next, a structure of a laminate that uses the semiconductor devices according to the second exemplary embodiment will be described with reference to FIGS. 3A and 3B.

FIGS. 3A and 3B are cross-sectional diagrams each showing an example of a laminate of semiconductor devices where a plurality of semiconductor devices according to the second exemplary embodiment are laminated. First semiconductor device 17 and second semiconductor device 18 shown in FIGS. 3A and 3B have the same structure as the semiconductor device shown in FIG. 2, and has a step at each lead 4.

According to the laminate of semiconductor devices shown in FIG. 3A, first semiconductor device 17 and second semiconductor device 18 are arranged with first surfaces 25 of respective leads 4 facing each other. That is, first surfaces 25 of leads 4 of first semiconductor device 17 and first surfaces 25 of leads 4 of second semiconductor device 18 are connected by solders 13 to form a laminate

According to such a structure, first and second semiconductor devices 17 and 18 may both have the outermost surface on the side of second surface 6 of semiconductor substrate 1 where circuit 23 is formed exposed without the outermost surface being covered by sealing material 3. Also, second surface 6 of semiconductor substrate 1 of second semiconductor device 18 faces opposite direction from first semiconductor device 17 on the lower side, and thus heat dissipation may be prevented from being reduced due to circuit 23 arranged on second surface 6 being sandwiched between sealing materials 3 of first and second semiconductor devices 17 and 18.

To further enhance heat dissipation, the laminate of semiconductor devices of the present modification may have heat sink 5 attached to the surface of second semiconductor device 18 where circuit 23 is formed. For example, heat sink 5 is an alloy, such as Cu alloy or 42 alloy, and is joined to metal film 10 by solder 13.

Furthermore, first semiconductor device 17 may be mounted on mounting board 14. That is, second surfaces 26 of leads 4 of first semiconductor device 17 are connected by solders 13 to wiring lands 15 of mounting board 14. Here, mounting board 14 may include heat dissipation land 16 at a part facing semiconductor substrate 1, and metal film 10 of semiconductor substrate 1 may be connected to heat dissipation land 16 by solder 13. Heat dissipation land 16 penetrates in the thickness direction of mounting board 14.

As described above, according to the laminate of semiconductor devices shown in FIG. 3A, first semiconductor device 17 and second semiconductor device 18 are laminated with second surfaces 6 where circuits 23 of respective semiconductor substrates 1 are formed facing away from each other, and moreover, metal film 10 of semiconductor substrate 1 of first semiconductor device 17 may be connected to heat dissipation land 16 of mounting board 14 or metal film 10 of semiconductor substrate 1 of second semiconductor device 18 may be connected to heat sink 5, and high heat dissipation may be realized.

According to the laminate of semiconductor devices shown in FIG. 3B, first semiconductor device 17 and second semiconductor device 18 are arranged with second surfaces 26 of respective leads 4 facing each other, and heat sink 5 is provided between first semiconductor device 17 and second semiconductor device 18. That is, second surfaces 26 of leads 4 of first semiconductor device 17 and second surfaces 26 of leads 4 of second semiconductor device 18 are connected by solders 13 to form a laminate, and heat sink 5 is connected to metal film 10 of first semiconductor device 17 and metal film 10 of second semiconductor device 18 via solders 13.

According to such a structure, first and second semiconductor devices 17 and 18 both have the outermost surface on the side of second surface 6 of semiconductor substrate 1 where circuit 23 is formed exposed without the outermost surface being covered by sealing material 3, and heat sink 5 is attached to metal film 10, and thus high heat dissipation may be realized. Also, since one heat sink 5 may be shared between semiconductor devices 17 and 18 that are vertically laminated, the thickness may be reduced while enhancing heat dissipation.

Furthermore, first semiconductor device 17 may be mounted on mounting board 14. That is, first surfaces 25 of leads 4 of first semiconductor device 17 are connected to wiring lands 15 of mounting board 14 by solders 13.

Additionally, as in the example in FIG. 3A, mounting board 14 may include heat dissipation land 16 at a part facing semiconductor substrate 1.

As described above, according to the laminate of semiconductor devices shown in FIG. 3B, first semiconductor device 17 and second semiconductor device 18 are laminated with second surfaces 6 where circuits 23 of respective semiconductor substrates 1 are formed facing each other, and moreover, metal films 10 of semiconductor substrates 1 of first semiconductor device 17 and second semiconductor device 18 may be connected to common heat sink 5, and high heat dissipation and reduced thickness may be realized

Additionally, in the first and the second exemplary embodiments, instead of metal film 10, heat sink 5 may be embedded in sealing material 3 so as to be built into a package, and its lower surface may be exposed.

### Third Exemplary Embodiment

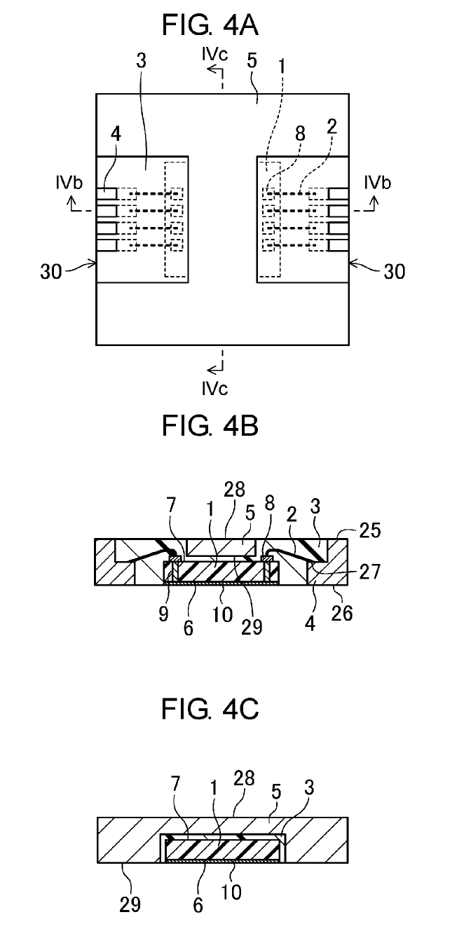

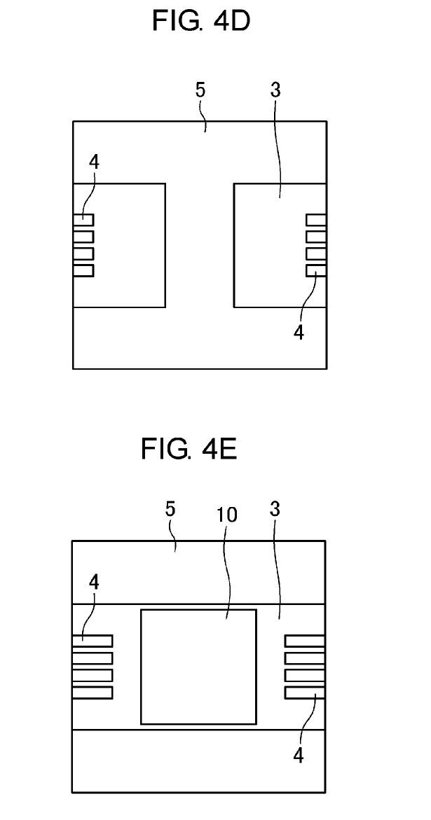

In the following, a structure of a semiconductor device according to a third exemplary embodiment will be described with reference to FIGS. 4A to 4E.

FIG. 4A is a diagram showing a semiconductor device according to the present exemplary embodiment from above, and is an internal perspective view showing the outer shape of semiconductor substrate 1, the arrangement of electrodes 8, leads 4 and connection members 2 inside sealing material 3 in a see-through manner. FIG. 4B is a cross-sectional diagram along the line

IVb-IVb in FIG. 4A, and FIG. 4C is a cross-sectional diagram along the line IVc-IVc in FIG. 4A. Also, FIG. 4D is a top view where sealing material 3 is not shown in a transparent manner, and FIG. 4E is a bottom view showing the semiconductor device from the bottom. Here, differences of the present exemplary embodiment to the second exemplary embodiment will be mainly described.

As shown in FIG. 4A, the semiconductor device according to the third exemplary embodiment includes heat sink 5 that is arranged above semiconductor substrate 1. First surface 28 of heat sink 5 is exposed from sealing material 3.

Heat sink 5 includes opening portions 30 at regions including connection members 2 and leads 4. Moreover, heat sink 5 is formed extending, at a region not including semiconductor substrate 1, to an outer peripheral portion of the semiconductor device, heat sink 5 having the same thickness as leads 4. On the other hand, the thickness of heat sink 5 at the region where semiconductor substrate 1 is included is thinner than the thickness at the outer peripheral portion so as to cover semiconductor substrate 1. That is, the region of heat sink 5 where semiconductor substrate 1 is included is positioned above semiconductor substrate 1.

As described above, according to the semiconductor device of the present exemplary embodiment, at the bottom surface of the semiconductor device, second surfaces 26 of leads 4, the outermost surface of semiconductor substrate 1 on the side of second surface 6, and first surface 28 at the outer peripheral portion of heat sink 5 are exposed from sealing material 3. Second surfaces 26 of leads 4, second surface 6 of semiconductor substrate 1, second surface 29 of heat sink 5 at the outer peripheral portion, and the bottom surface of sealing material 3 are desirably flush with one another. On the other hand, at the upper surface of the semiconductor device, first surfaces 25 of leads 4 and first surface 28 of heat sink 5 are exposed from sealing material 3. First surfaces 25 of leads 4, first surface 28 of heat sink 5, and the upper surface of sealing material 3 are desirably flush with one another.

According to such a structure, heat sink 5 may be extended farther than the outer peripheral portion of semiconductor substrate 1, and heat sink 5 may be formed to be large and thick at the outer peripheral portion of the semiconductor device. That is, since heat sink 5 may be maximized, the surface area of heat sink 5 is increased, and heat dissipation of the semiconductor device may be further enhanced.

Also, heat sink 5 may be formed, at the upper surface of semiconductor substrate 1, to have enough thickness to seal connection members 2 connecting electrodes 8 of semiconductor substrate 1 and internal terminals 27 of leads 4, and thus the thickness of the semiconductor device may be reduced. At the same time, the volume of sealing material 3 of the semiconductor device is reduced and the balance between upper and lower structures is improved, and thus the strength of the semiconductor device is increased, and damages and warpages may be reduced. That is, according to a semiconductor device with a built-in heat sink as described in the present exemplary embodiment, in addition to high heat dissipation, reduction in the thickness, productivity, and ease of lamination may be achieved.

Furthermore, the outer shape of the semiconductor device according to the present exemplary embodiment may be formed in the same manner as the semiconductor device in which a heat sink is not provided, and handling is easy compared to a conventional semiconductor device having an externally attached heat sink. Also, the manufacturing line, and jigs and tools may be shared with conventional products.

Moreover, in the present exemplary embodiment, electrodes 8 of semiconductor substrate 1 are concentrated at two parallel sides of semiconductor substrate 1, and heat sink 5 is formed to have an H-shape in plan view. Accordingly, two side surfaces of the semiconductor device may be made heat sink 5, and heat capacity and externally exposed area of heat sink 5 may be maximized, and also strength of the semiconductor device may be increased.

### Manufacturing Method of Third Exemplary Embodiment

Next, a manufacturing method for the semiconductor device according to the present exemplary embodiment will be described.

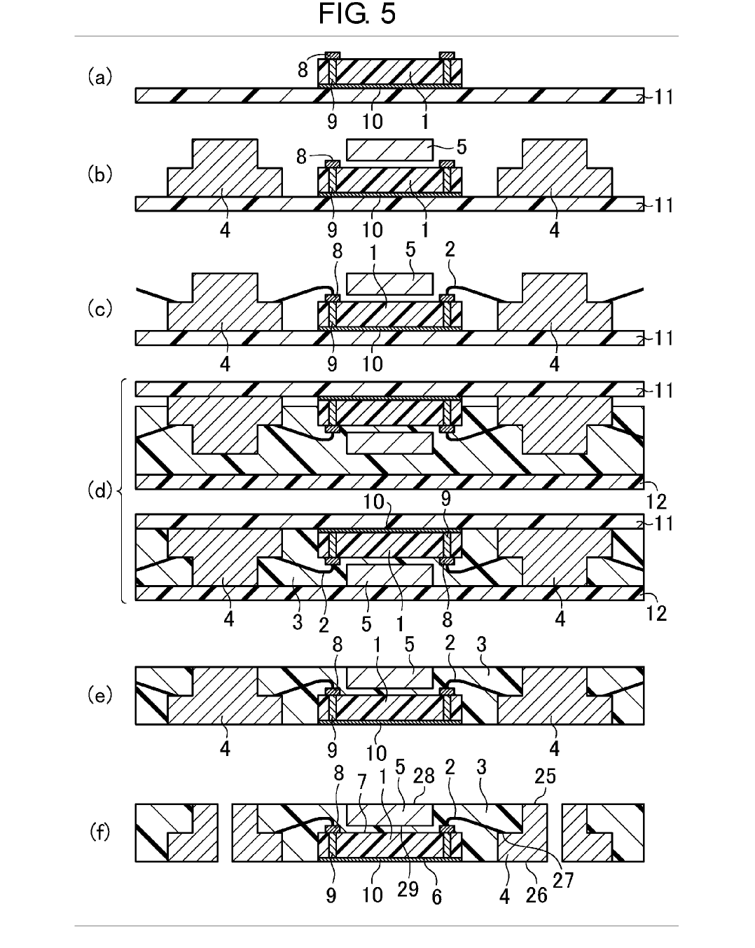

In FIG. 5, (a) to (f) show an example of a manufacturing process for the semiconductor device according to the present exemplary embodiment in the order of steps. In the following, (a) to (f) in FIG. 5 are denoted FIG. 5(a) to FIG. 5(f), respectively.

First, as shown in FIG. 5(a), the side of second surface 6 of semiconductor substrate 1 is attached to first release film 11. Release film 11 is to be removed after seal-molding, and uses polyimide, Teflon (registered trademark) or the like as a base material and a material that is heat resistant to 170° C. or higher, such as olefin, as an adhesive.

Next, as shown in FIG. 5(b), a lead frame including leads 4 and heat sink 5 is attached to release film 11.

Next, as shown in FIG. 5(c), electrodes 8 of semiconductor substrate 1 and leads 4 are connected by connection members 2.

Next, as shown in FIG. 5(d), semiconductor substrate 1, leads 4, connection members 2, and heat sink 5 are sealed with sealing material 3 by a compression molding method, for example. In this method, a liquid material is applied or printed or a granular material is sprayed on second release film 12, and the granular material is heated through second release film 12 and is melted. As sealing material 3, a thermosetting resin such as an epoxy resin is used.

Specifically, as shown in FIG. 5(d), the lead frame on which semiconductor substrate 1 is mounted and connection member bonding has been performed is positioned so as to face second release film 12, and the lead frame is pressed against second release film 12 with molten sealing material 3 between the lead frame and second release film 12, and the lead frame and second release film 12 are attached together and compressed, and semiconductor substrate 1, leads 4, connection members 2, heat sink 5, and sealing material 3 are integrated.

At this time, desirably, the thicknesses of leads 4 and the outer peripheral portion of heat sink 5 are the same, and the thickness of heat sink 5 above semiconductor substrate 1 is thinned by the amount of thickness of semiconductor substrate 1. Then, at the time of compression molding, the leads 4 and the outer peripheral portion of heat sink 5 interfere with a mold and are stopped before heat sink 5 comes into contact with semiconductor substrate 1, and damage due to interference between heat sink 5 and semiconductor substrate 1 may be automatically prevented. Also, since leads 4 and heat sink 5 function as spacers, the need for a mold may be eliminated.

As a result, heat sink 5 may be brought close to the main surface of semiconductor substrate 1 as much as possible, and at the same time, heat sink 5 may be maximized inside the device, at other than the region including semiconductor substrate 1 and connection members 2, and the heat dissipation effect may be maximized.

Note that, from the standpoint of heat dissipation effect, the gap between semiconductor substrate 1 and heat sink 5 is desirably minimized, but considering the damage to the main surface of semiconductor substrate 1, the gap has to be greater than the filler size of sealing material 3.

Practically, considering the variations in the thicknesses and parallelism of semiconductor substrate 1 and heat sink 5, and the filler size and filling properties of sealing material 3, the gap between semiconductor substrate 1 and heat sink 5 desirably ranges from 50 μm to 100 μm.

To further reduce the gap between semiconductor substrate 1 and heat sink 5, the filler size of sealing material 3 may be reduced, or the filler may even be eliminated.

Also, sealing material 3 may be used differently at between semiconductor substrate 1 and heat sink 5 and at other parts. For example, a small filler may be used or the filler may be eliminated only between semiconductor substrate 1 and heat sink 5.

Furthermore, by using leads 4 and heat sink 5 as spacers, the thickness of the semiconductor device may be controlled. In this case, since a mold cavity may be omitted, and seal-molding by a flat plate mold is enabled, and the shareability of mold is increased.

Moreover, in the present exemplary embodiment, the compression molding method is used, but it is also possible to perform seal-molding by a transfer molding method, a potting method, or printing as in conventional manners.

Then, after seal-molding, release films 11 and 12 are removed, as shown in FIG. 5(e), and dicing is performed to singulate the semiconductor device, as shown in FIG. 5(f).

Here, first surfaces 25 and second surfaces 26 of leads 4, first surface 28 and second surface 29 of heat sink 5, and second surface 6 of semiconductor substrate 1 are covered by release films in the step of sealing with sealing material 3. Accordingly, by removing the release films after molding, the first surface and the second surface of the semiconductor device may be exposed from the semiconductor device.

Moreover, by collectively molding and then dividing by dicing heat sinks 5 extending to the outer peripheral portions of the semiconductor devices, the cut surfaces of heat sinks 5 may be exposed at the outer peripheries of the semiconductor devices, and the exposed areas of heat sinks 5 may be maximized.

Now, if, at this time, heat sink 5 is inclined with respect to the outer shape, the cut surface of heat sink 5 may be varied for each piece due to a shift in the dicing position. However, in the present exemplary embodiment, opening portions 30, of heat sink 5 of the semiconductor device, at the connection member bonding regions are rectangular, and the entire shape of heat sink 5 is H-shaped in plan view, and thus heat sink 5 is perpendicular to the outer shape at all times. Accordingly, there are no uncut remnants, and the cut surfaces of pieces may be made uniform.

According to the example of manufacturing method of the present exemplary embodiment, the number of materials and steps are reduced by use of the lead frame integrating leads 4 and heat sink 5. Moreover, leads 4 and heat sink 5 may be separately provided, and may be integrated at the time of seal-molding.

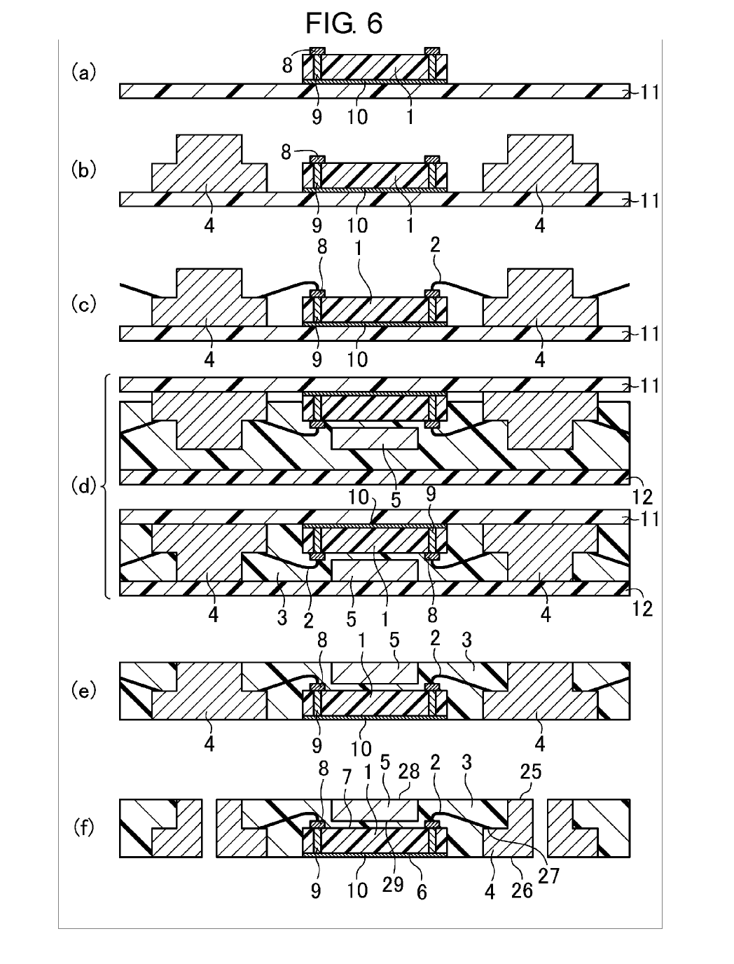

In FIG. 6, (a) to (f) show another example of the manufacturing process for the semiconductor device according to the present exemplary embodiment in the order of steps. In the following, (a) to (f) in FIG. 6 are denoted FIG. 6(a) to FIG. 6(f), respectively.

First, as shown in FIG. 6(a), second surface 6 of semiconductor substrate 1 is attached to first release film 11.

Next, as shown in FIG. 6(b), a lead frame including leads 4 is attached to release film 11.

Next, as shown in FIG. 6(c), electrodes 8 of semiconductor substrate 1 and leads 4 are connected by connection members 2.

Then, as shown in FIG. 6(d), heat sink 5 is attached to second release film 12.

Subsequently, as shown in FIG. 6(d), semiconductor substrate 1, leads 4, connection members 2, and heat sink 5 are sealed with sealing material 3 by the compression molding method, for example.

In this method, a liquid material is applied or printed, or a granular material is sprayed on second release film 12, and the granular material is heated through second release film 12 and is melted.

Specifically, as shown in FIG. 6(d), the lead frame on which semiconductor substrate 1 is mounted and connection member bonding has been performed is positioned so as to face second release film 12, and the lead frame is pressed against second release film 12 with molten sealing material 3 between the lead frame and second release film 12, and the lead frame and second release film 12 are attached together and compressed, and semiconductor substrate 1, leads 4, connection members 2, heat sink 5, and sealing material 3 are integrated.

The subsequent steps are the same as those described with reference to FIGS. 5(e) and 5(f), and description thereof is omitted.

According to the manufacturing method shown in FIGS. 6(a) to 6(f), since there is no heat sink 5 at the time of wire-bonding, the degree of freedom may be increased for the wire-bonding step and for the shape of heat sink 5.

Also, with respect to the semiconductor device in FIGS. 4A to 4E, semiconductor substrate 1 and heat sink 5 may be adhered in advance, and seal-molding may be performed after connection member bonding.

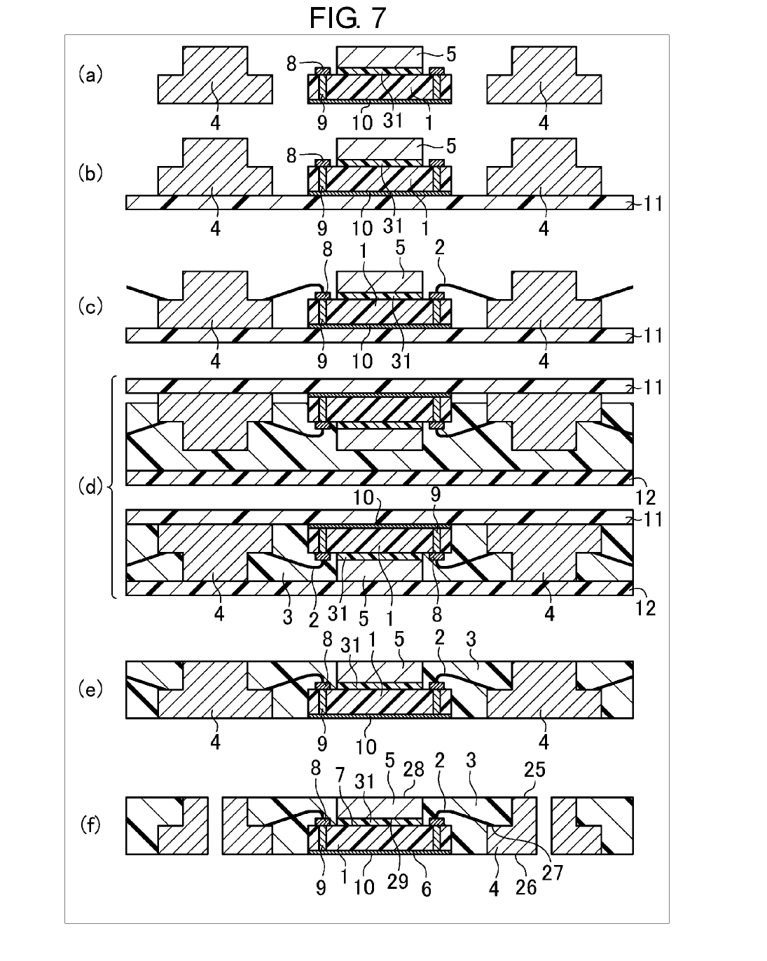

In FIG. 7, (a) to (f) show further another example of the manufacturing process for the semiconductor device according to the present exemplary embodiment in the order of steps. In the following, (a) to (f) in FIG. 7 are denoted FIG. 7(a) to FIG. 7(f), respectively.

First, as shown in FIG. 7(a), first surface 7 of semiconductor substrate 1 and second surface 29 of heat sink 5 on a lead frame are attached together. As adhesive member 31, a thermosetting resin such as an epoxy resin or an acrylic resin, a member which is a polyimide film whose both sides are coated with an adhesive, a metal such as solder, or the like may be used. To further enhance heat dissipation, a thermal conductive filler or the like may be mixed in adhesive member 31, or a metal such as solder may be used.

Next, as shown in FIG. 7(c), electrodes 8 of semiconductor substrate 1 and leads 4 are connected by connection members 2.

Then, as shown in FIG. 7(d), semiconductor substrate 1, leads 4, connection members 2, and heat sink 5 are sealed inside the mold with sealing material 3 by the compression molding method, for example.

In this method, a liquid material is applied or printed, or a granular material is scattered on second release film 12, and the granular material is heated through second release film 12 and is melted.

Specifically, as shown in FIG. 7(d), the lead frame on which semiconductor substrate 1 is mounted and connection member bonding has been performed is positioned so as to face second release film 12, and the lead frame is pressed against second release film 12 with molten sealing material 3 between the lead frame and second release film 12, and the lead frame and the second release film are attached together and compressed, and semiconductor substrate 1, leads 4, connection members 2, heat sink 5, and sealing material 3 are integrated.

The subsequent steps are the same as those described with reference to FIGS. 5(e) and 5(f), and description thereof is omitted.

Note that, from the standpoint of heat dissipation effect, the gap between semiconductor substrate 1 and heat sink 5 is desirably minimized, that is, semiconductor substrate 1 and heat sink 5 desirably contact each other via a protective film on semiconductor substrate 1.

According to the manufacturing method shown in FIGS. 7(a) to 7(f), sealing material 3 is not filled between semiconductor substrate 1 and heat sink 5, and the gap between semiconductor substrate 1 and heat sink 5, or the material of adhesive member 31 may be arbitrarily determined irrespective of sealing material 3, and heat dissipation may be enhanced.

Also, since semiconductor substrate 1 does not have to be attached to first release film 11, first release film 11 may be omitted.

As with the semiconductor device according to the second exemplary embodiment shown in FIG. 2, the semiconductor device of the present exemplary embodiment has leads 4 exposed from above and below the semiconductor device, and thus the semiconductor devices may be vertically laminated.

However, with the semiconductor device of the present exemplary embodiment, heat sink 5 is exposed from the upper and lower surfaces of the semiconductor device, on the same plane as leads 4, and thus when connecting leads 4 of upper and lower semiconductor devices to each other, heat sinks 5 of the upper and lower semiconductor devices may be coupled together.

Moreover, circuit 23 of semiconductor substrate 1 of the semiconductor device at the upper layer may be directly connected to heat sink 5 of the semiconductor device at the lower layer or a heat sink of the mounting board, and thus a laminate with high heat dissipation may be realized

### FIRST MODIFICATION OF THIRD EXEMPLARY EMBODIMENT

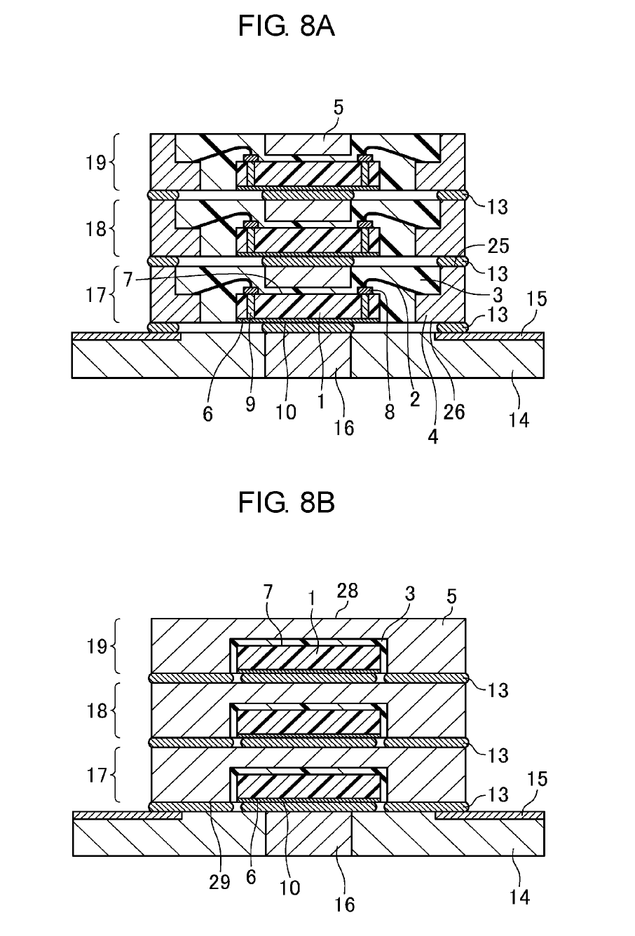

In the following, the structure of a laminate, according to a first modification of the third exemplary embodiment, that uses semiconductor devices will be described with reference to FIGS. 8A and 8B.

FIGS. 8A and 8B are views each showing a cross-sectional diagram of a laminate of semiconductor devices where a plurality of semiconductor devices according to the third exemplary embodiment are laminated.

FIG. 8A is a cross-sectional diagram along IVb-IVb in FIG. 4A where the semiconductor devices according to the third exemplary embodiment are laminated, and FIG. 8B is likewise a cross-sectional diagram along IVc-IVc in FIG. 4A.

First semiconductor device 17 is mounted on mounting board 14, and second semiconductor device 18 and third semiconductor device 19 are laminated in this order on semiconductor device 17.

Second surfaces 26 of leads 4 of first semiconductor device 17 are connected to wiring lands 15 of mounting board 14 by solders 13, and metal film 10 on second surface 6 of semiconductor substrate 1 of first semiconductor device 17 is connected to heat dissipation land 16 of mounting board 14 by solder 13.

Second surfaces 26 of leads 4 of second semiconductor device 18 are connected to first surfaces 25 of leads 4 of first semiconductor device 17 by solders 13, and metal film 10 on second surface 6 of semiconductor substrate 1 of second semiconductor device 18 is connected to first surface 28 of heat sink 5 of first semiconductor device 17 by solder 13.

Second surfaces 26 of leads 4 of third semiconductor device 19 are connected to first surfaces 25 of leads 4 of second semiconductor device 18 by solders 13, and metal film 10 on second surface 6 of semiconductor substrate 1 of third semiconductor device 19 is connected to first surface 28 of heat sink 5 of second semiconductor device 18 by solder 13.

Also, second surface 29 of heat sink 5 of first semiconductor device 17 is connected to wiring land 15 of mounting board 14 by solder 13. Second surface 29 of heat sink 5 of second semiconductor device 18 is connected to first surface 28 of heat sink 5 of first semiconductor device 17 by solder 13. Moreover, second surface 29 of heat sink 5 of third semiconductor device 19 is connected to first surface 28 of heat sink 5 of second semiconductor device 18 by solder 13. At this time, leads 4 of vertically laminated semiconductor devices are connected to each other, and thus a signal line that is output from each semiconductor device is made common.

With the laminate of semiconductor devices according to the present modification, heat of semiconductor substrates 1 of semiconductor devices 17 to 19 at respective layers may be efficiently dissipated. Also, with heat sink 5 being built in in each of semiconductor devices 17 to 19, soldering may be performed at the same time at the time of joining leads 4 by solder, and thus the materials and steps may be simplified.

Furthermore, since there is no need to externally attach heat sink 5, and the thickness of the product is not increased, the laminate may be made thin

Note that, in the present modification, solders 13 are used for connection between leads 4 of vertical semiconductor devices 17 to 19, and connection between semiconductor substrate 1 at the upper layer and heat sink 5 at the lower layer, but a method using other than soldering, such as a method using a conductive paste, may also be applied.

Also, connection between leads 4 of vertical semiconductor devices 17 to 19, and connection between semiconductor substrate 1 at the upper layer and heat sink 5 at the lower layer may be realized by different respective materials.

Furthermore, connection between metal film 10 of semiconductor substrate 1 at the upper layer and heat sink 5 at the lower layer may be mere contact.

Moreover, the number of laminated semiconductor devices may be arbitrarily set, and also vertical semiconductor devices may be semiconductor devices of different structures.

Furthermore, in the present modification, leads 4 and heat sinks 5 are exposed not only at the first surfaces and the second surfaces of semiconductor devices 17 to 19, but also at side surfaces of semiconductor devices 17 to 19, and thus leads 4 and heat sinks 5 may be arbitrarily connected in the side surface direction to enable electrical conduction or heat transfer. Accordingly, the semiconductor devices may be stacked three-dimensionally in vertical and horizontal directions, and electrical connection between the semiconductor devices and heat dissipation may be freely performed.

### Second Modification of Third Exemplary Embodiment

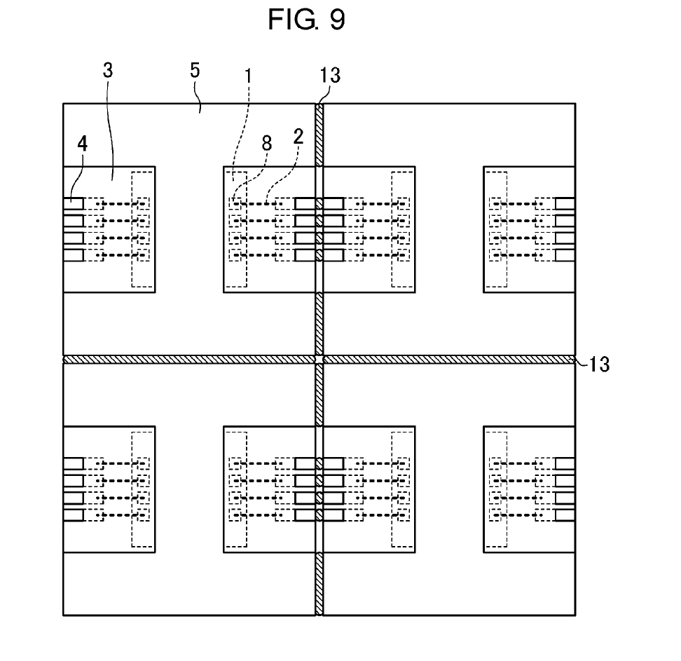

In the following, a structure of a connected body of semiconductor devices according to a second modification of the third exemplary embodiment will be described with reference to FIG. 9.

FIG. 9 is a top view of a connected body where a plurality of semiconductor devices according to the third exemplary embodiment are connected in the horizontal direction. At the side surfaces of respective semiconductor devices, leads 4 exposed from sealing materials 3 are made terminals, and are electrically connected by solders 13 or the like.

Moreover, side surfaces of heat sinks 5 are connected to each other by solder 13. According to such a structure, even when the amount of heat generation is varied among the semiconductor devices, heat may be transferred by connecting a plurality of heat sinks, and an effect of causing the temperature distribution to be close to being uniform may be obtained. That is, even if the amount of heat generation of a specific semiconductor substrate is larger compared to other semiconductor substrates, heat dissipation may be enhanced by the coupling structure of heat sinks 5, and deterioration in properties and the like due to heat may be prevented.

Note that, in the example shown in FIG. 9, all the facing terminals of the semiconductor devices are connected, but this is not restrictive, and it is also possible to connect only specific terminals. Also, adjacent heat sinks 5 do not need to have all of the facing parts connected.

Additionally, as will be described later, in the case where a greater number of signal lines are needed, heat sink 5 of the semiconductor device may be used as heat sink/second lead 21.

As described above, in the semiconductor devices according to the third exemplary embodiment and the modifications, the distance between heat sink 5 and semiconductor substrate 1 may be reduced as much as possible while preventing interference between heat sink 5 and connection member 2, and also the size of heat sink 5 inside the semiconductor device may be maximized, and thus the heat dissipation effect may be maximized.

Also, heat sinks 5 may be collectively sealed and formed in an integrated manner with semiconductor substrates 1 and the like for a plurality of semiconductor devices, and the semiconductor devices may be thinned and the productivity thereof may be increased compared to conventional products.

Furthermore, by arranging the semiconductor devices as a laminate or in the horizontal direction, connection in the vertical and horizontal direction may be freely performed, and paths for electrical conduction and heat transfer may be formed through the semiconductor substrate, and the degree of freedom regarding electrical wiring and heat dissipation paths may be significantly increased.

Also, the semiconductor device may be formed with heat sink 5 at a part of the main surface, other than the region of connection members 2, and at side surfaces, and is advantageous than conventional semiconductor devices in many aspects; for example, heat dissipation is enhanced, warpages are reduced, the strength is increased, and the reliability is increased.

### Fourth Exemplary Embodiment

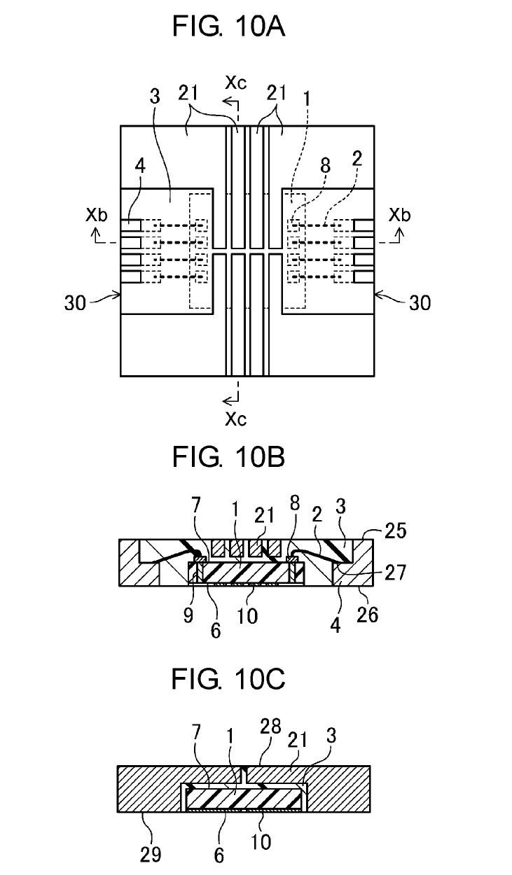

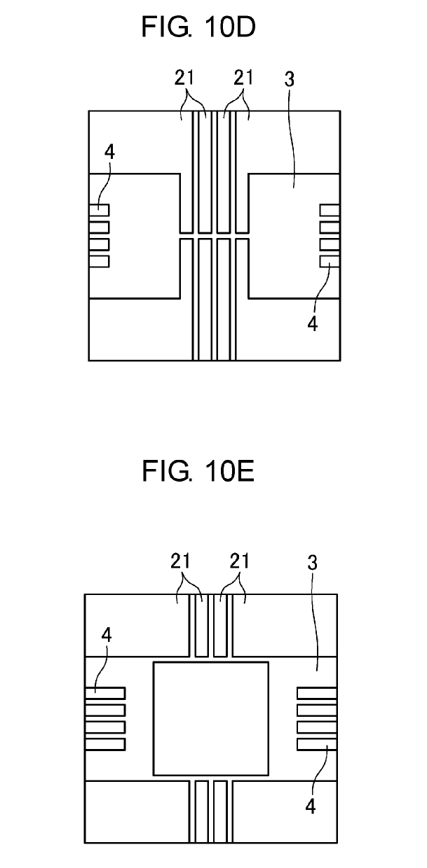

In the following, a structure of a semiconductor device according to a fourth exemplary embodiment will be described with reference to FIGS. 10A to 10E.

FIG. 10A is a diagram showing a semiconductor device according to the present exemplary embodiment from above, and is an internal perspective view showing the outer shape of semiconductor substrate 1, the arrangement of electrodes 8, leads 4 and connection members 2 inside sealing material 3 in a see-through manner. FIG. 10B is a cross-sectional diagram along Xb-Xb in FIG. 10A, and FIG. 10C is a cross-sectional diagram along Xc-Xc in FIG. 10A. Also, FIG. 10D is a top view where sealing material 3 is not shown in a transparent manner, and FIG. 10E is a bottom view showing the semiconductor device from the bottom. Here, differences of the present exemplary embodiment to the third exemplary embodiment will be mainly described.

In present exemplary embodiment, instead of heat sink 5, a plurality of second leads 21 that are divided in plan view are formed above second surface 7 of semiconductor substrate 1. Second leads 21 may be used as a structure for heat dissipation, as a terminal for signal transmission, or as both of them. That is, in addition to the function as a heat sink, second leads 21 may pass electrical signals from semiconductor substrate 1.

The material of second leads 21 may be the same as that of heat sink 5, but the material is chosen effectively by placing priority on thermal conductivity in the case where second leads 21 are to function mainly as heat sinks, and by placing priority on electrical conductivity in the case where the function as a terminal is needed.

In the present exemplary embodiment, at one semiconductor device, second leads 21 are merely arranged above first surface 7 of semiconductor substrate 1, and are not connected to the semiconductor substrate 1. Accordingly, for example, in the case where the semiconductor devices are laminated in such a way that leads 4 on the upper surface of the lower semiconductor device, shown in FIG. 10D, and leads 4 on the bottom surface of the upper semiconductor device, shown in FIG. 10E, are connected, second leads 21 of the upper and lower semiconductor devices are simply thermally connected.

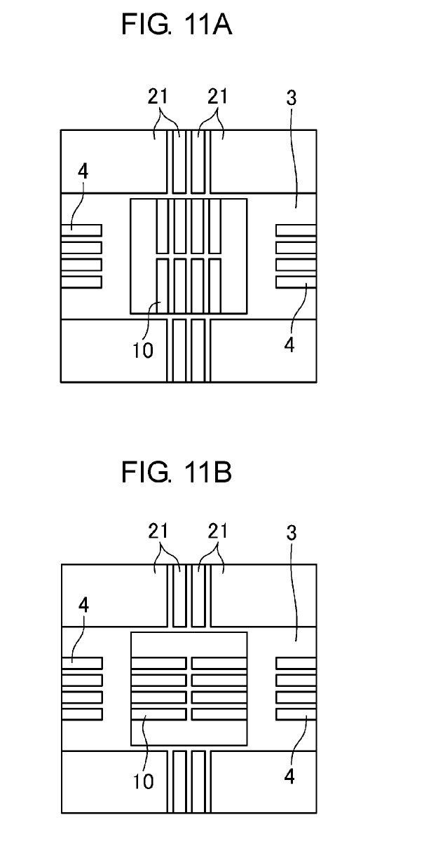

Additionally, as shown in FIG. 11A, metal film 10 arranged on second surface 6 of semiconductor substrate 1 may be formed being divided in accordance with the shape of second leads 21. That is, as shown in FIG. 11A, metal film 10 and heat sinks/second leads 21 are arranged in such a way that their lengthwise sides are along the same direction.

Therefore, at the time when the semiconductor devices are laminated, if the second leads are electrically conducted as signal paths, metal film 10 on semiconductor substrate 1 of the semiconductor device at the upper layer and second leads 21 of the lower layer may be prevented from being short-circuited at the time of connection. In the case of electrically connecting metal film 10 on semiconductor substrate 1 of the semiconductor device at the upper layer and second leads 21, metal film 10 may be divided.

Also, in the case where signal lines of upper and lower semiconductor devices that are laminated are desired to be separated, the semiconductor devices at the upper and lower layers may be laminated being 90 degrees rotated in the horizontal direction with respect to each other. For example, leads 4 on the upper surface of the lower semiconductor device, shown in FIG. 10D, and second leads 21 on the bottom surface of the upper semiconductor device, shown in FIG. 11A, are connected. Then, electrical signals from semiconductor substrate 1 of the upper semiconductor device passes through leads 4 and are conveyed to second leads 21 of the lower semiconductor device.

In this manner, in addition to having the heat dissipation function, second leads 21 may be used as signal paths.

Moreover, metal film 10 of semiconductor substrate 1 may be formed to have a shape that is 90 degrees rotated with respect to second leads 21 by assuming in advance that, in the case where semiconductor devices are to be laminated, the upper semiconductor device will be arranged being 90 degrees rotated in the horizontal direction with respect to the lower semiconductor device. That is, as shown in FIG. 11B, metal film 10 and second leads 21 are arranged with their lengthwise sides being orthogonal to each other.

Accordingly, even if the upper and lower semiconductor devices are arranged being 90 degrees rotated in the horizontal direction with respect to each other, connection may be established without second leads 21 and second surface 6 of semiconductor substrate 1 being short-circuited.

Moreover, in the fourth exemplary embodiment, second leads 21 may be connected not only in the lamination direction of the semiconductor devices, but also in the horizontal direction, and connection or formation of through passes may be freely performed in all the vertical and horizontal directions.

### Modification of Fourth Exemplary Embodiment

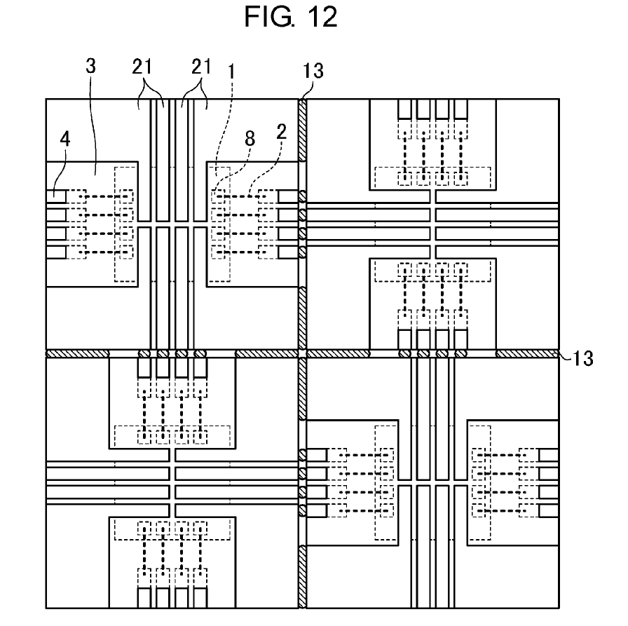

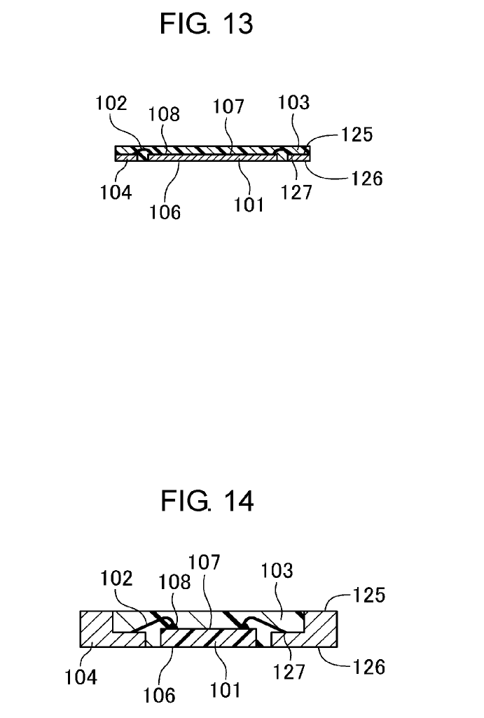

In the following, a modification of the fourth exemplary embodiment will be described with reference to FIG. 12.

A connected body of semiconductor devices according to the present modification may be structured by connecting the semiconductor devices as shown in FIG. 10A in horizontal direction, for example.

Adjacent semiconductor devices are arranged being 90 degrees rotated in the horizontal direction with respect to one another, and at the side surfaces, leads 4 and second leads 21 are connected with those of adjacent semiconductor devices. In FIG. 12, all the terminals of leads 4 and second leads 21 are connected by solders 13, but it is also possible to connect only some of the leads. Moreover, whether to rotate each semiconductor device by 90 degrees is not particularly specified.

The three-dimensional arrangement may significantly increase the degree of freedom regarding the electrical wiring and heat dissipation path, and is extremely useful.

Exemplary embodiments and modifications thereof have been described above as examples of the technology according to the present disclosure. The appended drawings and detailed description have been provided for this purpose.

Therefore, not only structural elements that are essential for solving the problems but also other structural elements that are not essential for solving the problems are included in the structural elements shown in the appended drawings and described in the detailed description for the purpose of exemplifying the technology. Hence, that these non-essential structural elements are shown in the appended drawings and described in the detailed description does not cause these structural elements to be immediately recognized as being essential.

Furthermore, the aforementioned exemplary embodiments and modifications are for exemplifying the technology according to the present disclosure, and various modifications, substitutions, additions, and omissions may be performed within the scope of claims and equivalents to the claims.

For example, in each of the exemplary embodiments and modifications described above, a surface-mounted leadless package that is similar to a wire-bonded QFN package is described as an example, but this is not restrictive. That is, the idea of arranging, on first surface 7 of semiconductor substrate 1, electrodes 8 that are connected to internal terminals 27, and of arranging circuit 23 on second surface 6 on the opposite side is effective for various packaging modes without being limited to the illustrated packages or by the presence/absence of connection member 2.

Also, a wire is described as an example of connection member 2, but this is not restrictive, and a lead or the like that is wider than a wire may alternatively be used.

Furthermore, a through electrode is illustrated as conductor 9, but this is not restrictive as long as the electrode on the first surface of semiconductor substrate 1 and the circuit on the second surface may be electrically connected.

Moreover, heat sink 5 is described to have a flat plate shape, but this is not restrictive as long as the effects described above may be achieved.

Moreover, the upper and lower surfaces and side surfaces of leads 4 and second leads 21 do not always have to be exposed, and the surfaces may be exposed according to the semiconductor device or a module.

The shapes of heat sink 5 and second leads 21 are assumed to be H-shaped where opening portions 30 are formed with connection members 2 concentrating at two facing sides of semiconductor substrate 1, but this is not restrictive, and arbitrary patterns may be adopted according to the needs regarding heat transfer and the design of wire connection between semiconductor substrates.

Moreover, circuit 23 and metal film 10 of semiconductor substrate 1 may be connected by providing an opening portion to insulating film 24, for example.

The present disclosure may be applied to electronic devices that are desired to achieve high heat dissipation and to be thinned/miniaturized. Specifically, the present disclosure may be widely applied to mobile appliances such as smartphones.

What is claimed is:

1. A semiconductor device comprising:
a semiconductor substrate;
an electrode disposed on a first surface of the semiconductor substrate;
a circuit formed on a second surface opposite to the first surface of the semiconductor substrate;
a conductor connecting the circuit and the electrode;
a first lead disposed on an outer periphery of the semiconductor substrate;
a connection member connecting the electrode and the first lead; and
a sealing material sealing the semiconductor substrate, the first lead, and the connection member,
wherein the second surface of the semiconductor substrate is exposed from the sealing material.

2. The semiconductor device according to claim 1, wherein an insulating film covering the circuit is provided on the second surface of the semiconductor substrate.

3. The semiconductor device according to claim 2, wherein a metal film covering the insulating film is provided.

4. The semiconductor device according to claim 1, wherein a second surface of the first lead is exposed from the sealing material.

5. The semiconductor device according to claim 3, wherein a second surface of the first lead and a second surface of the metal film are on a same plane.

6. The semiconductor device according to claim 1,
wherein a first surface of the first lead is exposed from the sealing material,
the first lead includes a step on a side facing the semiconductor substrate, and
the electrode is connected to the step via the connection member.

7. The semiconductor device according to claim 3, comprising a heat sink that is connected to the metal film.

8. The semiconductor device according to claim 1, comprising a heat sink that is disposed above the semiconductor substrate,
wherein the heat sink is sealed with the sealing material with a first surface of the heat sink exposed from the sealing material.

9. The semiconductor device according to claim 8, wherein a first surface of the sealing material and the first surface of the heat sink are on a same plane.

10. The semiconductor device according to claim 8, wherein the heat sink includes an opening portion at a region including the first lead and the connection member in a top view of the semiconductor device.

11. The semiconductor device according to claim 8, wherein a gap between the heat sink and the semiconductor substrate ranges from 50 μm to 100 μm.

12. The semiconductor device according to claim 1, wherein the conductor is a through electrode that connects the circuit and the electrode in a manner penetrating through the semiconductor substrate.

13. A laminate of semiconductor devices, the laminate comprising a semiconductor device according to claim 6 as a first semiconductor device and as a second semiconductor device,
wherein the second semiconductor device is mounted on the first semiconductor device in a manner overlapping the first semiconductor device in a plan view, and
the first surface of the first lead of the first semiconductor device and the first surface of the first lead of the second semiconductor device are connected facing each other.

14. A laminate of semiconductor devices, the laminate comprising a semiconductor device according to claim 6 as a first semiconductor device and as a second semiconductor device,
wherein the second semiconductor device is mounted on the first semiconductor device in a manner overlapping the first semiconductor device in a plan view, and
a second surface of the first lead of the first semiconductor device and a second surface of the first lead of the second semiconductor device are connected facing each other.

15. A laminate of semiconductor devices, the laminate comprising a semiconductor device according to claim 8 as a first semiconductor device and as a second semiconductor device,
wherein the second semiconductor device is mounted on the first semiconductor device in a manner overlapping the first semiconductor device in a plan view,
a first surface of the first lead of the first semiconductor device and a second surface of the first lead of the second semiconductor device are connected facing each other, and
the heat sink of the first semiconductor device is connected to the second semiconductor device.

16. The semiconductor device according to claim 3, comprising a second lead that is disposed above the semiconductor substrate,
wherein the second lead is sealed with the sealing material with a third surface exposed from the sealing material, the third surface being disposed on a same side as the first surface of the first lead, and
the first lead and the second lead are arranged in perpendicular directions.

17. The semiconductor device according to claim 16,
wherein the second lead is divided into a plurality of pieces,
the metal film is formed from a plurality of metal pieces, and
each of the plurality of metal pieces and the divided pieces of second lead are arranged with lengthwise sides being along a same direction.

18. The semiconductor device according to claim 16,
wherein the second lead is divided into a plurality of pieces,
the metal film is formed from a plurality of metal pieces, and
each of the plurality of metal pieces and the divided pieces of second lead are arranged with lengthwise sides being orthogonal to each other.

19. A laminate of semiconductor devices, the laminate comprising a semiconductor device according to claim 17 as a first semiconductor device and as a second semiconductor device,
wherein the second semiconductor device is mounted on the first semiconductor device in a manner overlapping the first semiconductor device in a plan view, and
each of the plurality of metal pieces of the first semiconductor device and the divided pieces of second lead of the second semiconductor device are connected with lengthwise sides being along a same direction.

20. A laminate of semiconductor devices, the laminate comprising a semiconductor device according to claim 18 as a first semiconductor device and as a second semiconductor device,
wherein the second semiconductor device is mounted on the first semiconductor device in a manner overlapping the first semiconductor device in a plan view, and
each of the plurality of metal pieces of the first semiconductor device and the divided pieces of second lead of the second semiconductor device are connected with lengthwise sides being orthogonal to each other.
